(19) United States
(12) Patent Application Publication
(10) Pub. No.: US 2006/0284256 A1
(43) Pub. Date: Dec. 21, 2006

(54) Layout structure for ESD protection circuits

(75) Inventors: Yi-Hsun Wu, Hsin-chu (TW); Kuo-Feng Yu, Hsin-chu (TW); Jian-Hsing Lee, Hsin-chu (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co.

(21) Appl. No.: 11/157,200

(22) Filed: Jun. 17, 2005

(51) Int. Cl. H01L 23/62

(52) U.S. Cl. 257/355

(57) ABSTRACT

The present invention provides a layout structure for an electrostatic discharge (ESD) protection circuit. The layout structure includes a first MOS device area, a second MOS device area, and a doped region. The first MOS device area has at least one source/drain region of a first polarity type. The second MOS device, which is adjacent to the first MOS device area, has at least one source/drain region of the first polarity type. A doped region of a second polarity type is interposed between the source/drain region of the first MOS device and the source/drain region of the second MOS device, such that the doped region and the source/drain regions interfacing therewith forming one or more diodes for dissipating ESD charges during an ESD event.

### BACKGROUND

The present invention relates generally to an integrated circuit (IC) design, and more particularly to a layout design for an electrostatic discharge (ESD) protection circuit.

A gate oxide of a metal-oxide-semiconductor (MOS) device of an IC is most susceptible to damage caused by ESD. The gate oxide may be destroyed by being contacted with a voltage only a few volts higher than a supply voltage of the IC. Electrostatic voltages from common environmental sources can easily reach thousands, or even tens of thousands of volts. Such voltages are destructive even though the charge and any resulting current are extremely small. For this reason, an ESD protection circuit is often implemented along with other core circuits in an IC in order to discharge any static electric charge, before it damages the IC.

Silicon-on-insulator (SOI) technology becomes more and more popular for low-voltage, high-speed applications because of its advantages over bulk-silicon technology, such as latch-up immunity and smaller junction capacitance. A diode is a conventional ESD protection device used in the SOI technology. The diode is one of the powerful devices used for on-chip ESD protection due to its low trigger voltage, low turn-on resistance, and high ESD robustness. However, this conventional diode does not provide an effective protection capability against negative ESD charges.

A conventional device often used for ESD protection against the negative ESD charges is the T-gate PMOS device constructed by using SOI technology. The T-gate PMOS device is featured by a T-shaped poly-silicon gate layer disposed above a source/drain doped region. However, the T-gate PMOS does not provide effective ESD protection against positive ESD charges as so provided by the diode.

Therefore, desirable in the art of the ESD protection circuit in SOI technology are layout structures for ESD protection circuits that provide effective protection against both the positive and negative ESD charges.

### SUMMARY

The present invention provides a layout structure for an electrostatic discharge (ESD) protection circuit. The layout structure includes a first MOS device area, a second MOS device area, and a doped region. The first MOS device area has at least one source/drain region of a first polarity type. The second MOS device, which is adjacent to the first MOS device area, has at least one source/drain region of the first polarity type. A doped region of a second polarity type is interposed between the source/drain region of the first MOS device and the source/drain region of the second MOS device, such that the doped region and the source/drain regions interfacing therewith form one or more diodes for dissipating ESD charges during an ESD event.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 illustrates a layout structure of a conventional diode.

FIG. 2 illustrates a layout structure of a conventional T-gate PMOS device.

FIG. 3 illustrates a layout structure of an ESD protection circuit in accordance with one embodiment of the present invention.

### DESCRIPTION

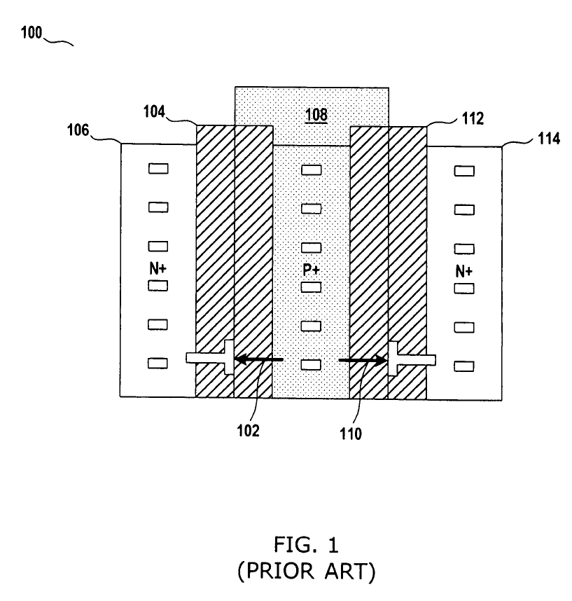

FIG. 1 illustrates a layout structure 100 for a set of conventional diodes used in SOI technology. Each of the conventional diodes within the layout structure 100 is made of an N+ and P+ doped region interfacing with one another. For example, a diode 102 includes a poly-silicon layer 104, an N+ doped region 106, and

a P+ doped region 108 while another diode 110 includes a poly-silicon layer 112, an N+ doped region 114, and a P+ doped region 108.

These diodes are typically used for on-chip ESD protection due to its low trigger voltage, low turn-on resistance, and high ESD robustness. However, the conventional diode, when it is used alone for ESD protection without the implementation of any transistors, does not provide an effective protection capability against the negative ESD charges.

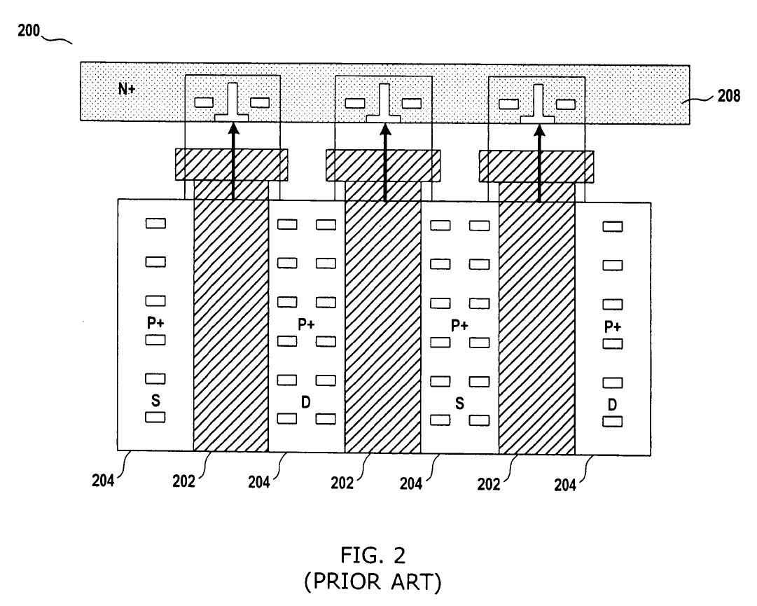

FIG. 2 illustrates a layout structure 200 for a set of conventional T-gate PMOS devices used in SOI technology. Each of the conventional T-gate transistors within the layout structure 200 includes of a poly-gate layer 202 with a P+ source/drain region 204 formed on both sides thereof. The poly-gate layer 202 has a T-shaped configuration. The P+ source/drain regions 204 may be used as either the drains or the sources of the PMOS devices. An N+ doped region 208 is formed as a well-contact for wells that are not shown in the figure, and it is understood by those skilled in the art that it is implemented under the P+ source/drain region 204.

The T-gate PMOS device, when it is used alone for ESD protection without implementation of any diodes, does not provide an effective protection capability against the positive ESD charges. Thus, it is desired to have an ESD protection circuit that includes both the diodes and T-gate PMOS devices for protecting core circuits against both the positive and negative ESD charges. Moreover, it is further desired to have a compact layout structure that realizes the ESD protection circuit including both the diodes and T-gate PMOS devices.

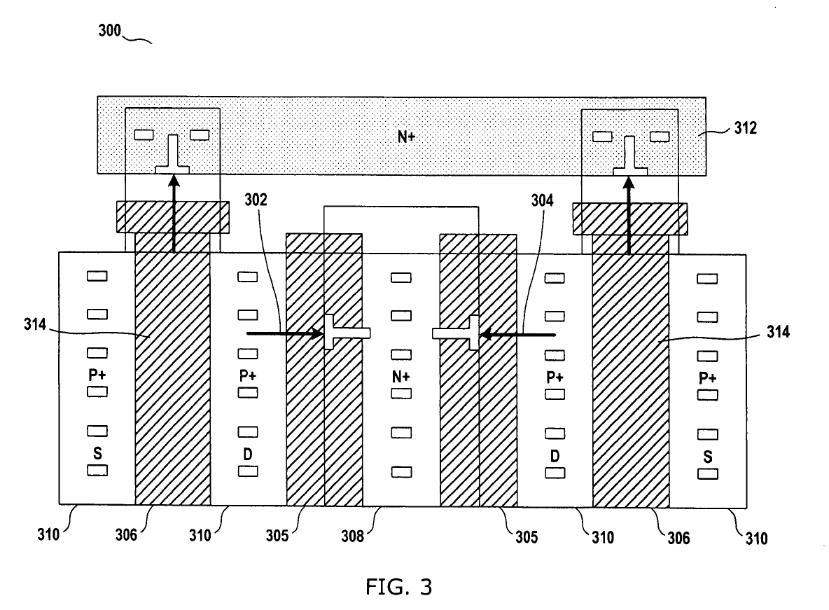

FIG. 3 illustrates a layout structure 300 for an ESD protection circuit that includes a set of T-gate PMOS devices and a set of diodes for providing ESD protection against both the positive and negative ESD charges in accordance with one embodiment of the present invention. The set of diodes is formed by interposing an N+ doped region between the P+ source/drain regions of the PMOS devices. This sandwiched arrangement of doped regions can be repeated in any number of times in a layout structure. Thus, the diodes and the T-gate PMOS devices can be constructed in a compact configuration.

Each of the T-gate PMOS device areas 314 includes a poly-gate layer 306, which forms is a part of the gate structure, and P+ source/drain regions 310 formed on both sides of the poly-gate layer 306. The P+ source/drain regions 310 may be used as either the drains or the sources of the PMOS devices. The diodes 302 and 304 within the layout structure 300 are made of an N+ doped region 308 and its neighboring P+ source/drain regions 310. One or more poly-silicon layers 305 are formed on a borderline of the N+ doped region 308 and its neighboring source/drain regions 310. An N+ doped region 312 is formed as a well-contact for wells that are not shown in the figure, and it is understood by those skilled in the art that it is implemented under the P+ source/drain regions 310.

In this embodiment, the N+ dope region 308 and the PMOS device areas 314 are constructed on a silicon layer separated from a semiconductor substrate by an insulation layer using the SOI technology. The silicon layer, insulation layer and the semiconductor substrate are not shown in the figure for clarity purposes. The N+ doped region 308 has a width between about 1e-3 um and 1e3 um. Its longitudinal side interfacing with the P+ source/drain regions 310 provides a PN junction for the diodes 302 and 304. The N+ doped region 308 can be formed with a dopant density between about 1e10 cm⁻³ and 1e24 cm⁻³, by an ion implantation technology at an implantation energy level between about 0 eV and 1000 M eV. It is noted that in another embodiment, the polarity of the doped regions, such as 310 and 308, can be switched.

With the T-gate PMOS device areas 314 and the diodes 302 and 304 implemented to provide an ESD protection circuit layout structure, the ESD protection capability against the positive ESD can improve as opposed to that of the T-gate PMOS devices without diodes implemented. Table I compares the ESD protection capability of the ESD protection circuit using the proposed layout structure with an ESD protection device that only uses the T-gate PMOS devices:

TABLE I

| Structure | Device size | −IT2/Vcc | +IT2/Vcc |
|---|---|---|---|
| T-G | 360 μm | 0.52 A | −0.2 A |
| T-G + D | 360 μm | 0.52 A | −0.9 A |
| T-G | 600 μm | 0.9 A | −0.3 A |
| T-G + D | 600 μm | 0.9 A | −4.2 A |

Table I shows results of eight different tests, which provide the maximum ESD current sinking capability for eight different ESD circuits. Out of the eight tests, four tests were performed under a positive ESD current scenario while the other four tests were performed under a negative ESD current scenario. The results from tests of the negative ESD current scenario are shown in the column under “−IT2/Vcc,” while the results from the tests of the positive ESD current scenario are shown in the column under “+IT2/Vcc.” Two different device sizes are used within the tests; the first size category is for devices of a total width of 360 μm, while the second size category is for devices of a total width of 600 μm. Within each size category, a circuit using the T-gate PMOS devices alone and a circuit having both the T-gate PMOS devices and the diodes were tested.

Under the positive ESD current scenario, the test results differ dramatically between the circuits that are implemented with the T-gate PMOS devices alone and the circuits integrated with both the T-gate PMOS devices and the diodes. The maximum current capability of the circuits integrated with both the T-gate PMOS devices and the diodes is much higher than the circuits that are implemented with only the T-gate PMOS devices. This is true for both size categories that were tested. For example, for devices of a total width of 360 μm, the ESD current sinking capability according to the invention is −0.9A, while the ESD current sinking capability according to a conventional circuit design with T-gate PMOS devices alone is −0.2A.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

1. A layout structure for an electrostatic discharge (ESD) protection circuit, comprising:
a first MOS device area having at least one P-type source/drain region;
a second MOS device area having at least one P-type source/drain region, adjacent to the first MOS device area; and
an N+ doped region interposed between the source/drain region of the first MOS device and the source/drain region of the second MOS device, such that the doped region and the source/drain regions interfacing therewith forming one or more diodes for dissipating ESD charges during an ESD event,
wherein there is no silicide around the N+ doped region.

2. (canceled)

3. The layout structure of claim 1 further comprising at least one poly-silicon layer formed on a borderline of the doped region and the source/drain region of the first or second MOS device that interfaces therewith.

4. The layout structure of claim 1 wherein the doped region has a width between about 1e-3 um and 1e3 um.

5. The layout structure of claim 1 wherein the first MOS device area, the second MOS device area, and the doped region are constructed on a semiconductor layer that is separated from a semiconductor substrate by an insulation layer.

6. The layout structure of claim 1 wherein the doped region has a dopant density between about 1e10 cm-3 and 1e24 cm-3.

7. The layout structure of claim 6 wherein the doped region is doped with impurities by using an ion implantation technology.

8. The layout structure of claim 7 wherein the doped region is doped with impurities at an implantation energy level between about 0 eV and 1000M eV.

9. A layout structure for an electrostatic discharge (ESD) protection circuit, comprising:
a silicon layer separated from a semiconductor substrate by an insulation layer;
a first MOS device area having at least one P-type source/drain region formed on the silicon layer;
a second MOS device area having at least one P-type source/drain region formed on the silicon layer in a location adjacent to the first MOS device area; and
an N+ doped region interposed between the source/drain region of the first MOS device and the source/drain region of the second MOS device, such that the doped region and the source/drain regions interfacing therewith forming one or more diodes for dissipating ESD charges during an ESD event,
wherein there is no silicide around the N+ doped region.

10. (canceled)

11. The layout structure of claim 9 further comprising at least one poly-silicon layer formed on a borderline of the doped region and the source/drain region of the first or second MOS device that interfaces therewith.

12. The ESD protection circuit layout structure of claim 9 wherein the doped region has a width between about 1e-3 um and 1e3 um.

13. The ESD protection circuit structure of claim 9 wherein the doped region has a dopant density between about 1e 10 cm-3 and 1e24 cm-3.

14. The ESD protection circuit layout structure of claim 13 wherein the doped region is doped with impurities by using an ion implantation technology.

15. The ESD protection circuit layout structure of claim 14 wherein the doped region is doped with impurities at an implantation energy level between about 0 eV and 1000M eV.

16. A layout structure for an electrostatic discharge (ESD) protection circuit, comprising:
a silicon layer separated from a semiconductor substrate by an insulation layer;
a first PMOS device area having a first poly-gate layer above the silicon layer and at least one first P-type source/drain region formed adjacent to the first poly-gate layer on the silicon layer;
a second PMOS device area having a second poly-gate layer above the silicon layer and at least one second P-type source/drain region formed adjacent to the second poly-gate layer on the silicon layer, wherein the second PMOS device area is adjacent to the first MOS device area; and
an N+ doped region interposed between the first P-type source/drain region and the second P-type source/drain region, such that the N-type doped region and the first and second P-type source/drain regions interfacing therewith forming one or more diodes for dissipating ESD charges during an ESD event,
wherein there is no silicide around the N+ doped region
wherein the doped region has a width between about 1e-3 um and 1 e3 um.

17. (canceled)

18. The layout structure of claim 16 wherein the doped region has a dopant density between about 1e10 cm-3 and 1e24 cm-3.

19. The layout structure of claim 18 wherein the doped region is doped with impurities by using an ion implantation technology.

20. The layout structure of claim 19 wherein the doped region is doped with impurities at an implantation energy level between about 0 eV and 1000M eV.

21. The layout structure of claim 1 wherein there is no silicide between the N+ doped region and the first MOS device.

22. The layout structure of claim 1 wherein there is no silicide between the N+ doped region and the second MOS device.

23. The layout structure of claim 9 wherein there is no silicide between the N+ doped region and the first MOS device.

24. The layout structure of claim 9 wherein there is no silicide between the N+ doped region and the second MOS device.

25. The layout structure of claim 16 wherein there is no silicide between the N+ doped region and the first MOS device.

26. The layout structure of claim 16 wherein there is no silicide between the N+ doped region and the second MOS device.
